(19) United States
(12) Patent Application Publication
(10) Pub. No.: US 2019/0190538 A1
(43) Pub. Date: Jun. 20, 2019

(54) ACCELERATOR HARDWARE FOR COMPRESSION AND DECOMPRESSION

(71) Applicant: Facebook, Inc., Menlo Park, CA (US)

(72) Inventors: Jong Soo Park, Mountain View, CA (US); Nadav Rotem, Santa Clara, CA (US); Mikhail Smelyanskiy, Burlingame, CA (US); Abdulkadir Utku Diril, Menlo Park, CA (US)

(21) Appl. No.: 15/846,110

(22) Filed: Dec. 18, 2017

(51) Int. Cl. H03M 7/30; G06N 3/02

(52) U.S. Cl. CPC H03M 7/6011; H03M 7/70; G06N 3/02

(57) ABSTRACT

A system may include a memory device that stores parameters of a layer of a neural network that have been compressed. The system may also include a special-purpose hardware processing unit programmed to, for the layer of the neural network: (1) receive the compressed parameters from the memory device, (2) decompress the compressed parameters, and (3) apply the decompressed parameters in an arithmetic operation of the layer of the neural network. Various other methods, systems, and accelerators are also disclosed.

### BACKGROUND

Artificial intelligence (AI) can enable computers to perform various complicated tasks, such as tasks related to cognitive functions that are typically associated with humans. Several approaches to AI are prevalent, including machine learning techniques. In machine learning systems, a computer may be programmed to parse data, learn from the data, and make predictions from real-world inputs. Some machine learning algorithms may use known data sets to train a computer to perform a task rather than explicitly programming the computer with a particular algorithm for performing the task. One machine learning model, referred to as an artificial neural network, was inspired by the interconnections of neurons in a biological brain.

Neural networks are modeled after neurons, using connected layers similar to connected neurons. Each layer may receive an input, process the input, and pass an output to the next layer until the final layer produces a final output. Each layer may also assign a weight to its input. For example, if a task involves identifying a particular object in an image, filter weights may correspond to a probability that the input matches the particular object. Calculations performed at these various layers may be computationally intensive, and the advent of dedicated processing units have made processing these neural network layers more feasible, especially for complex tasks related to computer vision or natural language processing.

While advancements in specialized processing hardware, such as AI accelerators, may provide ever-increasing computational power, many existing computing systems may be unable to support the full processing capabilities of some accelerators. For example, an AI accelerator may be capable of handling more matrix multiplication throughput (or other neural network processing operations) than a system's communication infrastructure can support. What is needed, therefore, is a more efficient and effective mechanism for utilizing the capabilities of hardware accelerators within various types of computing systems.

### SUMMARY

As will be described in greater detail below, the instant disclosure details various systems and methods for reducing bandwidth consumption for memory accesses performed by an AI accelerator by compressing data written to memory and decompressing data read from memory after the data is received at the AI accelerator. For example, a computing system may include a memory device that stores compressed parameters for a layer of a neural network and a special-purpose hardware processing unit programmed to, for the layer of the neural network: (1) receive the compressed parameters from the memory device, (2) decompress the compressed parameters, and (3) apply the decompressed parameters in an arithmetic operation of the layer of the neural network.

In some embodiments, the memory device may include a static memory cache that is local relative to the hardware processing unit, and the static memory cache may retain the compressed parameters in the static memory cache while the layer of the neural network is being processed. Additionally or alternatively, the memory device may include a dynamic memory device that is remote relative to the special-purpose hardware processing unit.

According to various examples, the computing system may include a compression subsystem that is communicatively coupled to the memory device and configured to compress the model data and store the compressed data in the memory device. In such embodiments, the special-purpose hardware processing unit may include the compression subsystem. Additionally or alternatively, the compression subsystem may be configured to compress the model data by (1) distinguishing between sparse and non-sparse data in the parameters and (2) applying a compression algorithm to the parameters based on the distinguished sparse and the non-sparse data in the parameters. Furthermore, in these and other embodiments, the compression subsystem may be configured to compress the model data by implementing a lossy compression algorithm.

In certain embodiments, the hardware processing unit may be further programmed to update the parameters of the layer, compress the updated parameters, and store the compressed, updated parameters in the memory device. In such embodiments, the hardware processing unit may update the parameters based on a compression scheme that will be used to compress the parameters.

A special-purpose hardware accelerator is also disclosed. The special-purpose hardware accelerator may include a processing unit configured to, for a layer of a neural network: (1) receive parameters for the layer of the neural network from a memory device, (2) decompress parameters for the layer from the model data, and (3) apply the decompressed parameters in an arithmetic operation. The special-purpose hardware accelerator may also include a cache for storing the parameters locally on the special-purpose hardware accelerator.

In some embodiments, the cache may store the parameters by retaining the parameters in the cache while the layer of the neural network is being processed. Additionally or alternatively, the processing unit may receive the compressed parameters from a memory device that is remote relative to the special-purpose hardware accelerator.

According to some examples, the special-purpose hardware accelerator may include a compression subsystem that is configured to compress the parameters before the parameters are stored in the cache. Furthermore, a compression algorithm for compressing the parameters for storage in the cache may be less complex and/or more lossy than a compression algorithm for compressing the parameters for storage in the remote memory device.

A method for hardware-based decompression is also disclosed. The method may include (1) compressing parameters of a layer of a neural network, (2) storing the compressed parameters in a memory device, (3) receiving, at a special-purpose hardware accelerator, the compressed parameters from the memory device, (4) decompressing, at the special-purpose hardware accelerator, parameters for the layer from the compressed model data, and (5) applying, at the special-purpose hardware accelerator, the decompressed parameters in an arithmetic operation.

In some embodiments of the method, the memory device may be a static memory cache that is local relative to the hardware processing unit. In such embodiments, the memory device may store the compressed parameters by caching the compressed parameters while the layer of the neural network is being processed. Additionally or alternatively, the memory device may include a dynamic memory device that is remote relative to the special-purpose hardware accelerator. Furthermore, compressing the parameters may involve compressing the parameters via a lossy compression algorithm.

In certain examples, the method may further include the steps of (1) updating the parameters of the layer, (2) compressing the updated parameters, and (3) storing the compressed, updated parameters in the memory device.

Features from any of the above-mentioned embodiments may be used in combination with one another in accordance with the general principles described herein. These and other embodiments, features, and advantages will be more fully understood upon reading the following detailed description in conjunction with the accompanying drawings and claims.

### BRIEF DESCRIPTION OF THE DRAWINGS

The accompanying drawings illustrate a number of exemplary embodiments and are a part of the specification. Together with the following description, these drawings demonstrate and explain various principles of the instant disclosure.

FIG. 1 is a block diagram of an exemplary system capable of utilizing an accelerator with compression and/or decompression features.

FIG. 2 is a diagram of an exemplary neural network capable of benefiting from the accelerator disclosed herein.

FIG. 3 is a block diagram of an exemplary convolutional neural network capable of benefiting from the accelerator disclosed herein.

FIG. 4 is a diagram depicting a data flow of compressed and decompressed data.

FIG. 5 is a block diagram of an exemplary accelerator configured for compression and/or decompression.

FIGS. 6A and 6B are flow diagrams of exemplary methods for compression and decompression within an accelerator.

FIG. 7 is a block diagram of an exemplary computing system capable of implementing one or more of the embodiments described and/or illustrated herein.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the instant disclosure covers all modifications, equivalents, and alternatives falling within the scope of the appended claims.

### DETAILED DESCRIPTION OF EXEMPLARY EMBODIMENTS

The present disclosure is generally directed to accelerator hardware with on-board support for data decompression. In some neural network systems, processing throughput for one or more layers may be limited by memory bandwidth between an inference accelerator and a memory device. To increase layer throughput, embodiments of the instant disclosure may compress various parameters (e.g., model data) of the layer when the parameters are written to memory. These compressed parameters, which may utilize less memory bandwidth than when uncompressed, may be fetched by an inference accelerator and, after being received at the inference accelerator, may be decompressed for use in layer processing. In this way, embodiments of the present disclosure may reduce memory bandwidth requirements and/or consumption of an AI accelerator and/or may provide a variety of other features and advantages in neural network processing and/or other AI-related computing tasks.

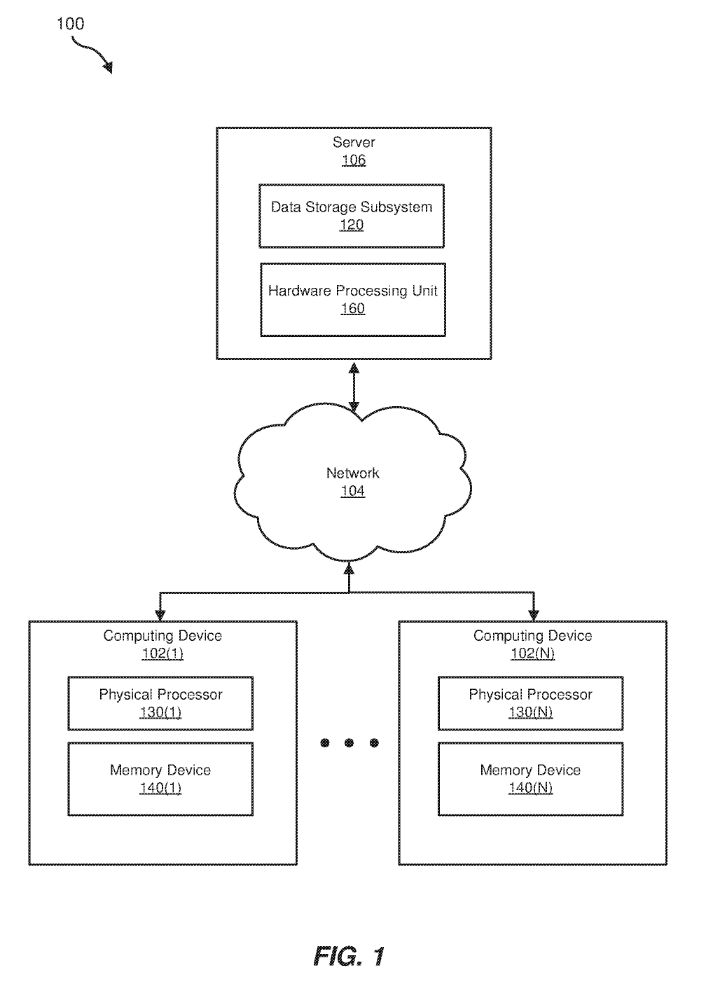

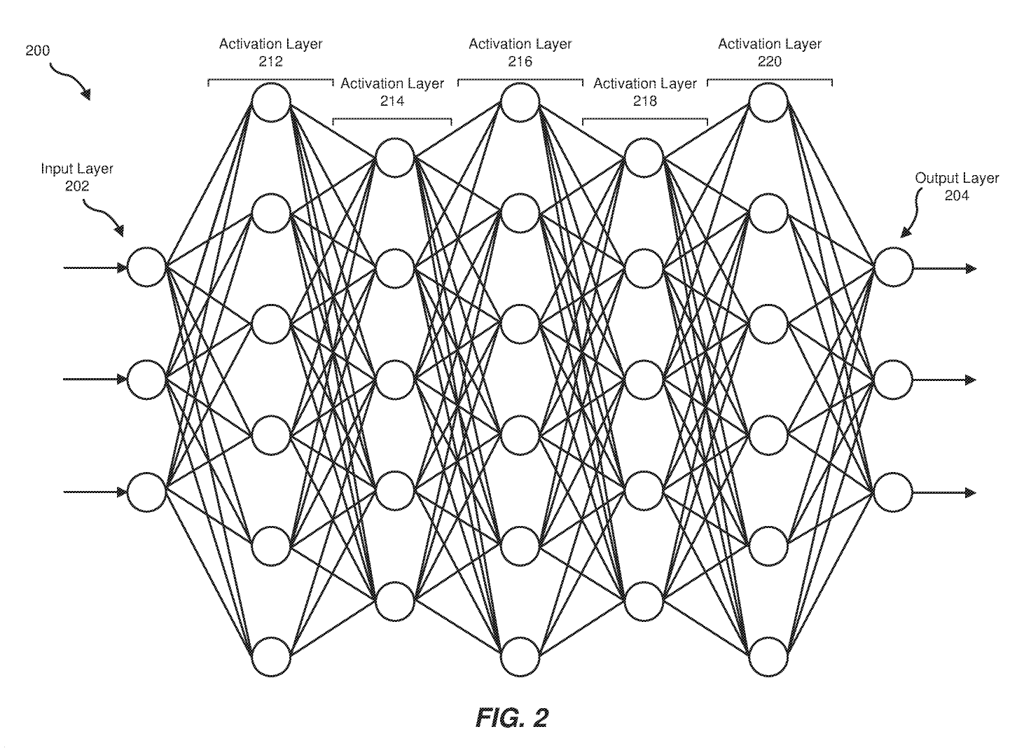

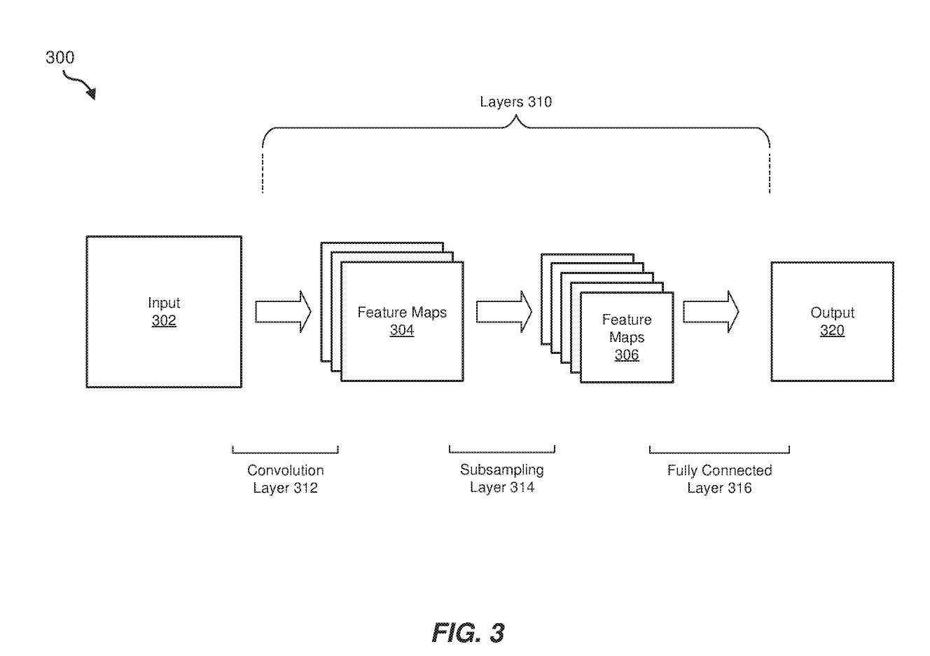

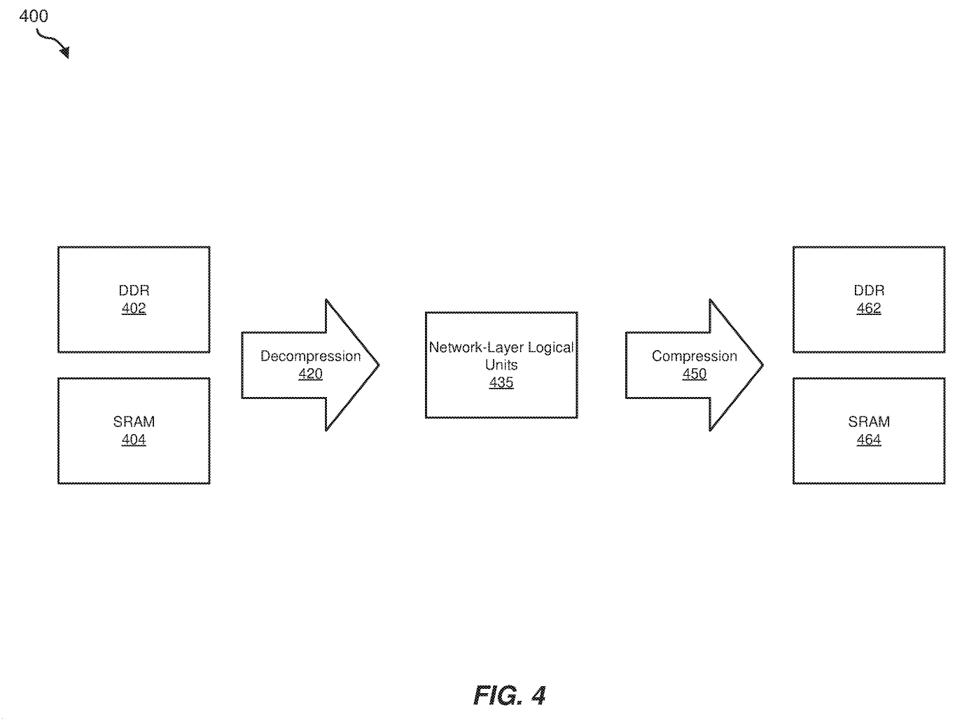

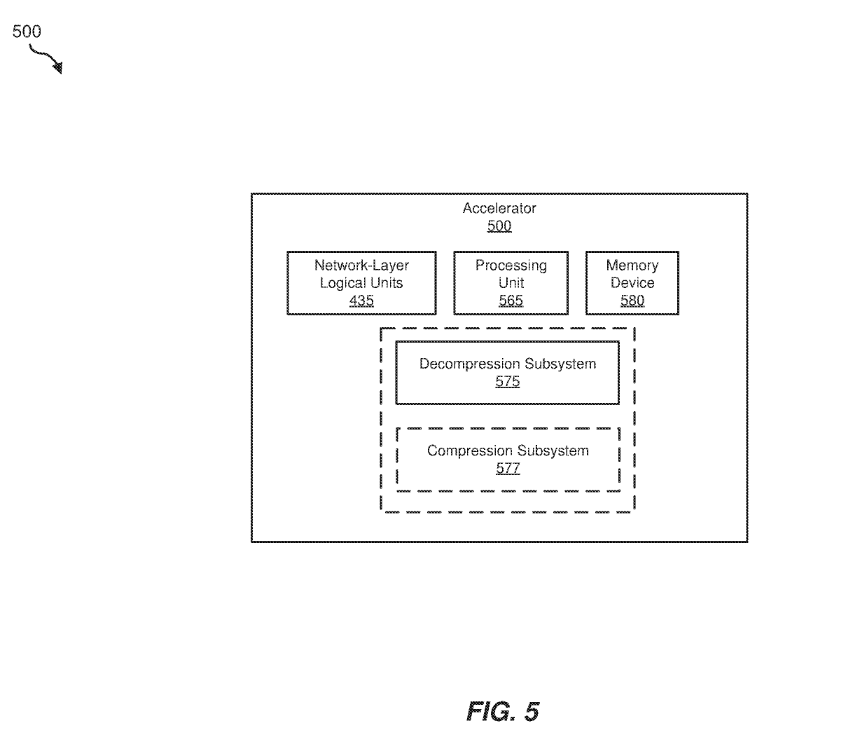

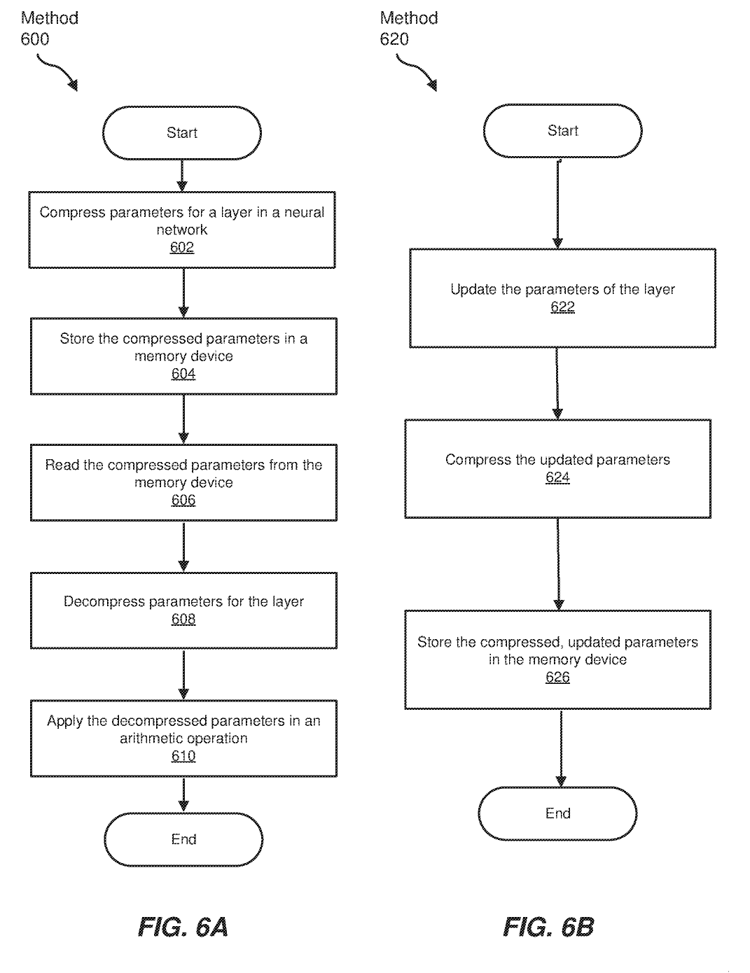

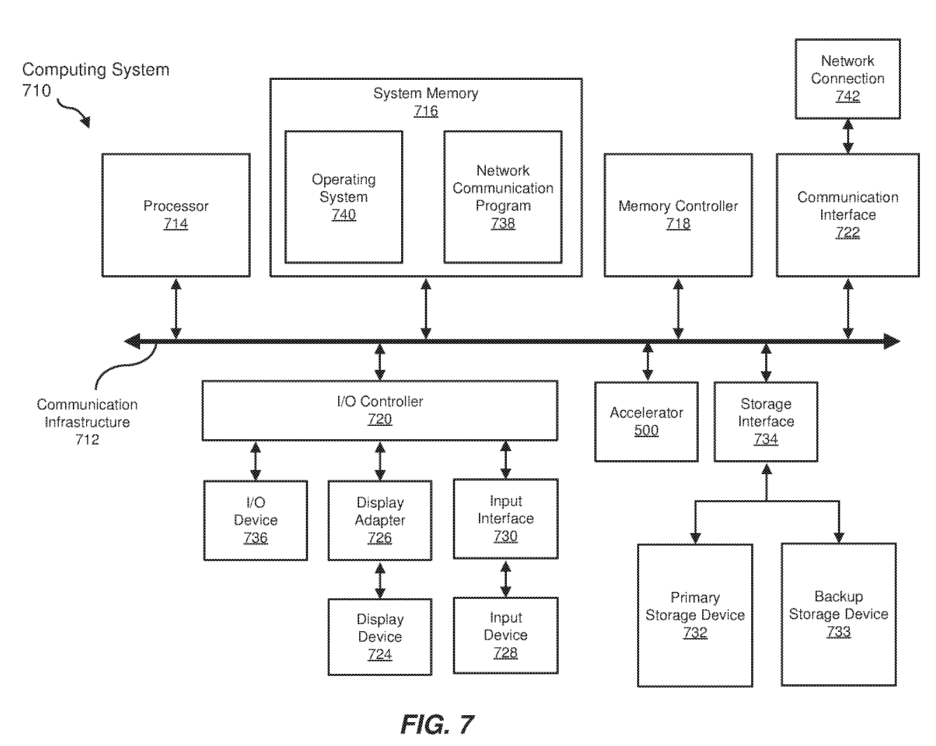

Turning to the figures, the following will provide, with reference to FIG. 1, detailed descriptions of an exemplary network environment in which an accelerator with compression and decompression features may be utilized. The following also provides, with reference to FIGS. 2 and 3, a discussion of exemplary neural networks that may benefit from the accelerators described herein. The description of FIG. 4 discusses aspects of a data flow that utilizes compression and decompression. The discussion of FIG. 5 presents an exemplary accelerator according to aspects of the present disclosure. The discussion of FIGS. 6A-6B covers processes for compression and decompression with accelerators. The following also provides, with reference to FIG. 7, an example of a computing system with a central processing unit (CPU) capable of implementing some of the steps or processes discussed herein.

FIG. 1 illustrates an exemplary network environment 100 (such as a social network environment) in which aspects of the present disclosure may be implemented. As shown, network environment 100 may include a plurality of computing devices 102(1)-(N), a network 104, and a server 106. Computing devices 102(1)-(N) may each represent a client device or a user device, such as a desktop computer, laptop computer, tablet device, smartphone, or other computing device. Each of computing devices 102(1)-(N) may include a physical processor (e.g., physical processors 130(1)-(N)), which may represent a single processor or multiple processors, and a memory device (e.g., memory devices 140(1)-(N)), which may store instructions (e.g., software applications) or data.

Computing devices 102(1)-(N) may be communicatively coupled to server 106 through network 104. Network 104 may be any communication network, such as the Internet, a Wide Area Network (WAN), or a Local Area Network (WAN), and may include various types of communication protocols and physical connections.

As with computing devices 102(1)-(N), server 106 may represent a single server or multiple servers (e.g., a data center). Server 106 may host a social network or may be part of a system that hosts the social network. Server 106 may include a data storage subsystem 120, which may store instructions as described herein, and a hardware processing unit 160, which may include one or more processors and data storage units used for performing inference calculations for layers of a neural network. In some examples, the term “inference” generally refers to the process of causing a trained neural network to apply the learning from training to new data. Similarly, the term “training,” in some examples, generally refers to the process of using a training dataset to teach a neural network new inference (e.g., classification) capabilities.

The term “hardware processing unit” may, in some examples, refer to various types and forms of computer processors. In some examples, a hardware processing unit may include a central processing unit and/or a chipset corresponding to a central processing unit. Additionally or alternatively, a hardware processing unit may include a hardware accelerator (e.g., an AI accelerator, a video processing unit, a graphics processing unit, etc.) and may be implemented via one or more of a variety of technologies (e.g., an application-specific integrated circuit (ASIC), a field-programmable gate array (FPGA), etc.).

The term “special-purpose hardware” may, in some examples, refer to various types and forms of processors and other logical units and hardware elements that may be arranged, designed, or otherwise configured to perform one or more tasks more efficiently than general purpose computing systems (e.g., general purpose processors and/or memory devices). For example, some of the special-purpose hardware described herein may be configured to perform matrix multiplication more efficiently and/or effectively than general purpose CPUs.

As noted, server 106 may host a social network, and in such embodiments, computing devices 102(1)-(N) may each represent an access point (e.g., an end-user device) for the social network. In some examples, a social network may refer to any type or form of service that enables users to connect through a network, such as the internet. Social networks may enable users to share various types of content, including web pages or links, user-generated content such as photos, videos, and posts, and/or to make comments or message each other through the social network.

In some embodiments, server 106 may access data (e.g., data provided by computing devices 102(1)-(N)) for analysis. For example, server 106 may perform various types of machine learning tasks on data. For instance, server 106 may use machine learning algorithms to perform speech recognition (e.g., to automatically caption videos), to enable computer vision (e.g., to identify objects in images, to classify images, to identify action in video, to turn panoramic photos into interactive 360 images, etc.), in recommender systems (e.g., information filtering systems that predict user preferences), for facial recognition and human pose estimation, in document analysis, and/or to perform a variety of other tasks.

In addition to being applied in a variety of technical fields, embodiments of the instant disclosure may also be applied to numerous different types of neural networks. For example, the systems and methods described herein may be implemented in any AI scheme that is designed to provide brain-like functionality via artificial neurons. In some examples (e.g., recurrent neural networks and/or feed-forward neural networks), these artificial neurons may be non-linear functions of a weighted sum of inputs that are arranged in layers, with the outputs of one layer becoming the inputs of a subsequent layer.

FIG. 2 is a block diagram of an exemplary feed-forward neural network 200 capable of benefiting from the accelerators described herein. Neural network 200 may include an input layer 202, an output layer 204, and a series of five activation layers—activation layer 212, activation layer 214, activation layer 216, activation layer 218, and activation layer 220. While FIG. 2 provides an example with five activation layers, neural network 200 may include any other suitable number of activation layers (e.g., one activation layer, dozens of activation layers, thousands of activation layers, etc.).

In the example shown in FIG. 2, data flows from input layer 202 through activation layers 212-220 to output layer 204 (i.e., from left to right). As shown, each value from the nodes of input layer 202 may be duplicated and sent to the nodes of activation layer 212. At activation layer 212, a set of weights (i.e., a filter) may be applied to the layer inputs, and each node may output a weighted sum to activation layer 214. This process may be repeated at each activation layer in sequence to create outputs at output layer 204.

While FIG. 2 shows one way to conceptualize a feed-forward neural network, there are a variety of other types of neural networks and ways to illustrate and conceptualize neural networks. For example, FIG. 3 shows a neural network 300 capable of benefiting from the accelerators described herein. As such in this figure, neural network 300 may include a variety of different types of layers 310 (some which may be fully connected feed-forward layers, such as those shown in FIG. 2). In convolution layer 312, an input 302 may undergo convolutional transformations, which may be calculated by hardware such as hardware processing unit 160, accelerator 500, and/or processor 714. For example, input 302 may undergo convolutions based on the filters and quantization parameters of convolution layer 312 to produce feature maps 304. In some embodiments, convolution layer 312 may also include a rectification sublayer (e.g., a layer implemented via a rectified linear unit, also known as a RELU layer) with an activation function.

FIG. 3 also shows that feature maps 304 output by convolution layer 312 may undergo subsampling (e.g., pooling), based on the filters and parameters of subsampling layer 314, to produce feature maps 306, which may be reduced-size feature maps. The convolution and subsampling of layers 312 and 314 may be performed a single time or multiple times before sending an output (e.g., feature maps 306) to a fully connected layer, such as fully connected layer 316. Fully connected layer 316, which FIG. 3 shows one example of, may process feature maps 306 to identify the most probable inference or classification for input 302 and may provide this classification or inference as output 320.

As explained above in the discussion of FIG. 3, in a convolutional neural network each activation layer may be a set of nonlinear functions of spatially nearby subsets of outputs of a prior layer. As noted, neural networks may also operate in a variety of other ways. For example, embodiments of the instant disclosure may be applied to a multi-layer perceptron (MLP), such as the example shown in FIG. 2, in which each activation layer is a set of nonlinear functions of the weighted sum of each output from a prior layer. Embodiments of the instant disclosure may also be applied to a recurrent neural network (RNN), in which each activation layer may be a collection of nonlinear functions of weighted sums of outputs and of a previous state. Embodiments of the instant disclosure may also be applied to any other suitable type or form of neural network.

As noted, a hardware accelerator may be specially configured to perform computations for layers of a neural network, and the performance of certain layers of the neural network may be limited by memory bandwidth (e.g., limited in the amount of data available on a memory channel) between the hardware accelerator and a memory device. Due to limited memory bandwidth available in memory channels between hardware accelerators and system memory, reading model data (e.g., weight matrices) from memory may create bottlenecks when the rate of data read is less than the rate at which the data may be processed. Thus, memory bottlenecks may impede optimal use of the computational capabilities of a hardware accelerator. The locations where model data is stored, which may be related to a type of memory device in which the model data is stored, may also affect latency and efficiency network layer processing.

In various embodiments, memory devices for storing compressed data may include any type or form of volatile or non-volatile storage device or medium capable of storing data. In some embodiments, a memory device may be separate from (e.g., remote from) an accelerator or may be located directly on (e.g., local to) an accelerator. Examples of memory devices may include dynamic memory devices (e.g., double data rate synchronous dynamic random-access memory (DDR SDRAM or DDR)) and static memory devices (e.g., static random-access memory (SRAM)).

In various embodiments, reducing memory bandwidth consumption may directly translate to accelerated computation in bandwidth-limited systems. Compressing data, which may reduce a size of the data, may serve to reduce bandwidth usage and therefore eliminate a memory-bandwidth bottleneck. In some embodiments, data may be compressed before being written to memory, and the compressed data may be read from memory and decompressed on an accelerator before being used in neural network computations. Compression may be applied to an entire set of parameters for a neural network layer or may be selectively applied, for example, to a subset of parameters of a neural network or layer. Certain data, such as filter weights, may be compressed and cached locally for all or a portion of the processing involved in a particular neural network layer (or set of neural network layers).

FIG. 4 shows a data flow 400 that depicts how data may be decompressed and compressed according to aspects of the present disclosure. Either or both of DDR 402 and SRAM 404 may store compressed parameters for a neural network. These parameters (e.g., model data) may have been compressed using any of a variety of different types of compression schemes. For example, a sparse-matrix compression scheme may be used to compress data. Examples of sparse-matrix compression schemes may include a compressed-sparse-row scheme (e.g., an algorithm that creates a format that may represent a matrix with one-dimensional arrays that contain (i) nonzero values, (ii) the extents of the rows, and (iii) the column indices), a dictionary of keys (e.g., a map of row-column pairs to element values, where missing elements are assumed to be zero), etc. Other examples of compression schemes may include lossless compression algorithms such as lookup tables with Huffman coding (e.g., an algorithm that assigns variable-length codes to inputs, where lengths of the assigned codes are based on frequencies of matrix elements) or other reversible compression techniques that allow original data to be completely reconstructed from the compressed data. Embodiments of the instant disclosure may also employ lossy (irreversible) compression techniques that may use inexact approximations and/or partial data discarding techniques.

At decompression step 420, data that is compressed in DDR 402 or SRAM 404 may be transferred to on-board decompression logic of an accelerator and may be cached for access by, or streamed directly to, network-layer logical units 435. For example, network-layer logical units 435 may request decompressed parameters for a network layer from a cache (e.g., SRAM 404), which may store compressed and/or decompressed data) and may receive a stream of decompressed data directly from decompression logic. Alternatively, network-layer logical units 435 may read or receive compressed parameters and may perform decompression within layer processing logic before using the parameters for layer processing operations.

Network-layer logical units 435 may apply the decompressed parameters in a variety of types of arithmetic operations. For example, the parameters may be applied in filtering or convolution operations, which may be matrix operations, or other operations such as RELU operations or pooling operations. In some embodiments, these parameters may be updated during execution of the layer (e.g., during backpropagation), as explained in greater detail below.

At compression step 450, the updated parameters may be recompressed, which may be performed by a local or remote compression subsystem using any suitable compression algorithm. The compressed, updated parameters may then be stored in SRAM 464 (e.g., for additional training and backpropagation updates) and/or in DDR 462 (e.g., for future use in inference). In some embodiments, DDR 402 and DDR 462 may represent different memory devices, may represent the same memory device, may represent the same locations within a single memory device, and/or may represent different locations within a single memory device. Similarly, SRAM 404 and SRAM 464 may represent different memory devices, may represent the same memory device, may represent the same locations within a single memory device, and/or may represent different locations within a single memory device.

In some embodiments, different types of compression may be selectively applied depending on the use and/or storage destinations of the compressed data. For example, data may be compressed using a complex lossless compression algorithm when being stored in DDR 462 since reads to DDR 462 may be dependent on memory bandwidth. Data that is to be stored on-chip on an accelerator may be compressed and decompressed with less aggressive, more lossy, and/or simpler compression schemes (e.g., these parameters may be used frequently and may therefore need to be compressed and/or decompressed rapidly) and stored in SRAM 464.

FIG. 5 shows an accelerator 500, which may implement aspects of the present disclosure, including hardware-based decompression and/or compression algorithms described above. Accelerator 500 may include network-layer logical units 435, a processing unit 565, a memory device 580, and a decompression subsystem 575. Accelerator 500 may also optionally include a compression subsystem 577, which may be an integral part of, or part of the same subsystem as, decompression subsystem 575.

Network-layer logical units 435 may include one or more logical units or other calculation hardware, such as matrix multipliers or general matrix-matrix multiplication (GEMM) units, tensor units, or other logical and/or arithmetic units used for performing calculations for a layer (e.g., as part of training and/or inference operations). Processing unit 565 may be a processor or other controller logic for coordinating operations of accelerator 500. Memory device 580 may be a memory device or other data storage unit for use during inference operations (e.g., for storing weights, output data, etc.) and may be part of a data storage subsystem of accelerator 500. In various examples, the phrase “data storage subsystem” generally refers to any type or combination of one or more data storage units, including registers, caches, random-access memory devices, etc.

Decompression subsystem 575 and compression subsystem 577 may include logical units or other hardware configured to decompress and compress data, respectively. In addition, decompression subsystem 575 and compression subsystem 577 may include embedded decompression and compression hardware, decompression and compression encoders, and/or any other components capable of decompressing and/or compressing parameters of a neural network. Decompression subsystem 575 and compression subsystem 577 may also be configured for performing one or more compression schemes, such as the algorithms discussed above.

FIG. 6A is a flow diagram of an exemplary computer-implemented method 600 for performing compression and/or decompression within an accelerator. The steps shown in FIG. 6A may be performed by any suitable computer-executable code and/or computing system, including the system(s) illustrated in FIGS. 1, 5, and 7. In one example, each of the steps shown in FIG. 6A may represent an algorithm whose structure includes and/or is represented by multiple sub-steps, examples of which will be provided in greater detail below.

As illustrated in FIG. 6A, at step 602 one or more of the systems described herein may compress model data for a layer in a neural network. For example, compression subsystem 577 in FIG. 5 may compress parameters for a layer in a neural network. Compression subsystem 577 may compress various type of parameters and may compress the parameters in various manners. In addition, model data may be compressed at any suitable time during network training, between training and inference, and/or during inference. Furthermore, all or a portion of the model data of a layer or network may be compressed, and different portions of the model data may be compressed using different compression schemes.

The compression scheme (or schemes) used by compression subsystem 577 to compress model data may have been selected based on an acceptable level of loss in compression, in order to reduce a latency for decompression, and/or based on any other criteria. In some embodiments, the compression scheme may be selected to maximize performance gains from reducing memory bandwidth. For example, a simple compression scheme may be implemented if a complex compression scheme would require significant overhead for decompression, which may negate any performance gains from memory bandwidth reduction.

The compression scheme may also be selected based on a variety of other factors. For example, compression subsystem 577, processing unit 565, and/or processor 714 may be configured to compress model data by distinguishing between sparse and non-sparse data in the model data, compressing only the sparse data (e.g., only compress sparse filter matrices), and then storing the model data based on whether and/or how the data was compressed.

At step 604, one or more of the systems described herein may store the compressed model data in a memory device in any suitable manner. For example, accelerator 500 may store the compressed data locally in memory device 580 or may write the compressed data to system memory 716 of computing system 710 in FIG. 7. Additionally or alternatively, processor 714 of computing system 710 may store compressed data in system memory 716 and/or may transmit compressed data to accelerator 500 for caching in memory device 580. Compressed data may be written to memory at any suitable time during network training, between training and inference, and/or during inference. Also, different portions of the compressed data may be stored in a local cache, a remote memory device, both, or neither.

At step 606, one or more of the systems described herein may read the compressed model data from the memory device. For example, processing unit 565 may read the compressed data from memory device 580 or fetch the compressed data from system memory 716 of computing system 710. Additionally or alternatively, processor 714 of computing system 710 may read the compressed data from system memory 716. Compressed data may be read from memory at any suitable time during network training, between training and inference, and/or during inference. Furthermore, all or a portion of the compressed model data for a layer may be read all at once and/or a portion at a time.

At step 608, one or more of the systems described herein may decompress the compressed parameters for the layer. For example, decompression subsystem 575 may decompress the parameters locally on accelerator 500 to provide decompressed parameters for use in a layer processing.

Decompression subsystem 575 may decompress the parameters in any suitable manner. In some embodiments, decompression subsystem 575 may be configured to recognize the compression scheme for the compressed model data and decompress the model data based on the identified compression scheme. Decompression subsystem 575 may decompress all the retrieved compressed model data and extract the parameters needed for a particular operation and/or may decompress only a subset of the retrieved model data.

At step 610, one or more of the systems described herein may apply the decompressed parameters in an arithmetic operation. For example, network-layer logical units 435 may receive the decompressed parameters from decompression subsystem 575 and may use the decompressed parameters in any suitable arithmetic operation (e.g., a multiply operation, an accumulate operation, a convolution operation, vector or matrix multiplication, etc.).

FIG. 6B is a flow diagram of an exemplary computer-implemented method 620 for providing compression and decompression support within an accelerator. The steps shown in FIG. 6B may be performed by any suitable computer-executable code and/or computing system, including the system(s) illustrated in FIGS. 1, 5, and 7. In one example, each of the steps shown in FIG. 6B may represent an algorithm whose structure includes and/or is represented by multiple sub-steps, examples of which will be provided in greater detail below.

The steps of method 620 may occur before, after, or during the steps of method 600. For instance, method 600 and method 620 may occur in series, in parallel, in cycles, etc. In some embodiments (e.g., if data is not to be written back to memory or cached), one or more steps of method 620 may not be performed.

At step 622, one or more of the systems described herein may update the parameters of the layer. For example, accelerator 500 and/or processor 714 of computing system 710 may update the parameter as a result of executing a current layer of a neural network and/or executing the entire network. For example, accelerator 500 may update the parameters as a result of training or may update the parameters based on input from another layer. In some embodiments, a neural network may be configured to update parameters and build filter maps with future compression of the parameters as a consideration (e.g., based on a compression scheme that will be used to compress the model data), and these updated filter maps may be compressed.

At step 624, one or more of the systems described herein may compress the updated parameters. For example, to reduce memory consumption, accelerator 500 or processor 714 of computing system 710 may compress the updated parameters before writing to memory. As noted, in some embodiments, compressing the updated parameters may include selecting a subset of the updated parameters. The subset of the updated parameters ay be parameters that are to remain on-chip (e.g., that are held in a cache) during an entire execution time for a layer and/or network. For example, the selected subset may be parameters that remain in memory device 580 for the entire time that accelerator 500 executes the layer and/or network. The subset of updated parameters may be selected based on a storage destination of the parameters. For example, parameters to be stored in DDR or parameters to be stored in SRAM may be specifically selected. The selected subset of parameters, rather than all of the updated parameters, may then be compressed.

At step 626, one or more of the systems described herein may store the compressed, updated parameters in the memory device to update the compressed parameters. For example, accelerator 500 or processor 714 of computing system 710 may send the compressed, updated parameters to the memory device for writing. The compressed, updated parameters may replace the existing compressed parameters in the memory device or may replace and/or update a portion of the compressed model data in the memory device. For example, compression subsystem 577 may compress the updated parameters and send the compressed updated parameters to a remote memory device. Alternatively, the compressed updated parameters may be cached in memory device 580 and/or subsequently sent to the memory device.

FIG. 7 is a block diagram of an example computing system 710 capable of implementing one or more of the embodiments described and/or illustrated herein. For example, all or a portion of computing system 710 may perform and/or be a means for performing, either alone or in combination with other elements, one or more of the steps described herein (such as one or more of the steps illustrated in FIGS. 6A-6B). All or a portion of computing system 710 may also perform and/or be a means for performing any other steps, methods, or processes described and/or illustrated herein. In some embodiments computing system may include accelerator 500, which may enable hardware-based decompression and/or compression that may alleviate potential bandwidth bottlenecks of communication infrastructure 712.

Computing system 710 broadly represents any single or multi-processor computing device or system capable of executing computer-readable instructions. Examples of computing system 710 include, without limitation, workstations, laptops, client-side terminals, servers, distributed computing systems, handheld devices, or any other computing system or device. In its most basic configuration, computing system 710 may include at least one processor 714 and a system memory 716.

Processor 714 generally represents any type or form of physical processing unit (e.g., a hardware-implemented central processing unit) capable of processing data or interpreting and executing instructions. In certain embodiments, processor 714 may receive instructions from a software application or module. These instructions may cause processor 714 to perform the functions of one or more of the example embodiments described and/or illustrated herein.

System memory 716 generally represents any type or form of volatile or non-volatile storage device or medium capable of storing data and/or other computer-readable instructions. Examples of system memory 716 include, without limitation, Random Access Memory (RAM), Read Only Memory (ROM), flash memory, or any other suitable memory device. Although not required, in certain embodiments computing system 710 may include both a volatile memory unit (such as, for example, system memory 716) and a non-volatile storage device (such as, for example, primary storage device 732, as described in detail below).

In some examples, system memory 716 may store and/or load an operating system 740 for execution by processor 714. In one example, operating system 740 may include and/or represent software that manages computer hardware and software resources and/or provides common services to computer programs and/or applications on computing system 710. Examples of operating system 740 include, without limitation, LINUX, JUNOS, MICROSOFT WINDOWS, WINDOWS MOBILE, MAC OS, APPLE'S IOS, UNIX, GOOGLE CHROME OS, GOOGLE'S ANDROID, SOLARIS, variations of one or more of the same, and/or any other suitable operating system.

In certain embodiments, example computing system 710 may also include one or more components or elements in addition to processor 714 and system memory 716. For example, as illustrated in FIG. 7, computing system 710 may include a memory controller 718, an Input/Output (I/O) controller 720, a communication interface 722, and an accelerator 500, each of which may be interconnected via a communication infrastructure 712. Communication infrastructure 712 generally represents any type or form of infrastructure capable of facilitating communication between one or more components of a computing device. Examples of communication infrastructure 712 include, without limitation, a communication bus (such as an Industry Standard Architecture (ISA), Peripheral Component Interconnect (PCI), PCI Express (PCIe), or similar bus) and a network.

Memory controller 718 generally represents any type or form of device capable of handling memory or data or controlling communication between one or more components of computing system 710. For example, in certain embodiments memory controller 718 may control communication between processor 714, system memory 716, and I/O controller 720 via communication infrastructure 712.

I/O controller 720 generally represents any type or form of module capable of coordinating and/or controlling the input and output functions of a computing device. For example, in certain embodiments I/O controller 720 may control or facilitate transfer of data between one or more elements of computing system 710, such as processor 714, system memory 716, communication interface 722, display adapter 726, input interface 730, and storage interface 734.

Accelerator 500 generally represents any type or form of module capable of performing calculations and other inference operations for a neural network. For example, accelerator 500 may be specialized hardware that includes one or more functional units and data storage units for dedicated neural network operations.

As illustrated in FIG. 7, computing system 710 may also include at least one display device 724 coupled to I/O controller 720 via a display adapter 726. Display device 724 generally represents any type or form of device capable of visually displaying information forwarded by display adapter 726. Similarly, display adapter 726 generally represents any type or form of device configured to forward graphics, text, and other data from communication infrastructure 712 (or from a frame buffer, as known in the art) for display on display device 724.

As illustrated in FIG. 7, example computing system 710 may also include at least one input device 728 coupled to I/O controller 720 via an input interface 730. Input device 728 generally represents any type or form of input device capable of providing input, either computer or human generated, to example computing system 710. Examples of input device 728 include, without limitation, a keyboard, a pointing device, a speech recognition device, variations or combinations of one or more of the same, and/or any other input device.

Additionally or alternatively, example computing system 710 may include additional I/O devices. For example, example computing system 710 may include I/O device 736. In this example, I/O device 736 may include and/or represent a user interface that facilitates human interaction with computing system 710. Examples of I/O device 736 include, without limitation, a computer mouse, a keyboard, a monitor, a printer, a modem, a camera, a scanner, a microphone, a touchscreen device, variations or combinations of one or more of the same, and/or any other I/O device.

Communication interface 722 broadly represents any type or form of communication device or adapter capable of facilitating communication between example computing system 710 and one or more additional devices. For example, in certain embodiments communication interface 722 may facilitate communication between computing system 710 and a private or public network including additional computing systems. Examples of communication interface 722 include, without limitation, a wired network interface (such as a network interface card), a wireless network interface (such as a wireless network interface card), a modem, and any other suitable interface. In at least one embodiment, communication interface 722 may provide a direct connection to a remote server via a direct link to a network, such as the Internet. Communication interface 722 may also indirectly provide such a connection through, for example, a local area network (such as an Ethernet network), a personal area network, a telephone or cable network, a cellular telephone connection, a satellite data connection, or any other suitable connection.

In certain embodiments, communication interface 722 may also represent a host adapter configured to facilitate communication between computing system 710 and one or more additional network or storage devices via an external bus or communications channel. Examples of host adapters include, without limitation, Small Computer System Interface (SCSI) host adapters, Universal Serial Bus (USB) host adapters, Institute of Electrical and Electronics Engineers (IEEE) 1394 host adapters, Advanced Technology Attachment (ATA), Parallel ATA (PATA), Serial ATA (SATA), and External SATA (eSATA) host adapters, Fibre Channel interface adapters, Ethernet adapters, or the like. Communication interface 722 may also allow computing system 710 to engage in distributed or remote computing. For example, communication interface 722 may receive instructions from a remote device or send instructions to a remote device for execution.

In some examples, system memory 716 may store and/or load a network communication program 738 for execution by processor 714. In one example, network communication program 738 may include and/or represent software that enables computing system 710 to establish a network connection 742 with another computing system (not illustrated in FIG. 7) and/or communicate with the other computing system by way of communication interface 722. In this example, network communication program 738 may direct the flow of outgoing traffic that is sent to the other computing system via network connection 742. Additionally or alternatively, network communication program 738 may direct the processing of incoming traffic that is received from the other computing system via network connection 742 in connection with processor 714.

Although not illustrated in this way in FIG. 7, network communication program 738 may alternatively be stored and/or loaded in communication interface 722. For example, network communication program 738 may include and/or represent at least a portion of software and/or firmware that is executed by a processor and/or ASIC incorporated in communication interface 722.

As illustrated in FIG. 7, example computing system 710 may also include a primary storage device 732 and a backup storage device 733 coupled to communication infrastructure 712 via a storage interface 734. Storage devices 732 and 733 generally represent any type or form of storage device or medium capable of storing data and/or other computer-readable instructions. For example, storage devices 732 and 733 may be a magnetic disk drive (e.g., a so-called hard drive), a solid state drive, a floppy disk drive, a magnetic tape drive, an optical disk drive, a flash drive, or the like. Storage interface 734 generally represents any type or form of interface or device for transferring data between storage devices 732 and 733 and other components of computing system 710.

In certain embodiments, storage devices 732 and 733 may be configured to read from and/or write to a removable storage unit configured to store computer software, data, or other computer-readable information. Examples of suitable removable storage units include, without limitation, a floppy disk, a magnetic tape, an optical disk, a flash memory device, or the like. Storage devices 732 and 733 may also include other similar structures or devices for allowing computer software, data, or other computer-readable instructions to be loaded into computing system 710. For example, storage devices 732 and 733 may be configured to read and write software, data, or other computer-readable information. Storage devices 732 and 733 may also be a part of computing system 710 or may be a separate device accessed through other interface systems.

Many other devices or subsystems may be connected to computing system 710. Conversely, all of the components and devices illustrated in FIG. 7 need not be present to practice the embodiments described and/or illustrated herein. The devices and subsystems referenced above may also be interconnected in different ways from that shown in FIG. 7. Computing system 710 may also employ any number of software, firmware, and/or hardware configurations. For example, one or more of the example embodiments disclosed herein may be encoded as a computer program (also referred to as computer software, software applications, computer-readable instructions, or computer control logic) on a computer-readable medium. The term “computer-readable medium,” as used herein, generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

The computer-readable medium containing the computer program may be loaded into computing system 710. All or a portion of the computer program stored on the computer-readable medium may then be stored in system memory 716 and/or various portions of storage devices 732 and 733. When executed by processor 714, a computer program loaded into computing system 710 may cause processor 714 to perform and/or be a means for performing the functions of one or more of the example embodiments described and/or illustrated herein. Additionally or alternatively, one or more of the example embodiments described and/or illustrated herein may be implemented in firmware and/or hardware. For example, computing system 710 may be configured as an ASIC adapted to implement one or more of the example embodiments disclosed herein.

Although illustrated as separate elements, the modules described and/or illustrated herein may represent portions of a single module or application. In addition, in certain embodiments one or more of these modules may represent one or more software applications or programs that, when executed by a computing device, may cause the computing device to perform one or more tasks. For example, one or more of the modules described and/or illustrated herein may represent modules stored and configured to run on one or more of the computing devices or systems described and/or illustrated herein. One or more of these modules may also represent all or portions of one or more special-purpose computers configured to perform one or more tasks.

In addition, one or more of the modules described herein may transform data, physical devices, and/or representations of physical devices from one form to another. For example, one or more of the modules recited herein may receive model data to be transformed, transform the model data, output a result of the transformation when processing a layer of a neural network, use the result of the transformation to update the model data, and store the result of the transformation to when processing the neural network. Additionally or alternatively, one or more of the modules recited herein may transform a processor, volatile memory, non-volatile memory, and/or any other portion of a physical computing device from one form to another by executing on the computing device, storing data on the computing device, and/or otherwise interacting with the computing device.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the instant disclosure. The embodiments disclosed herein should be considered in all respects illustrative and not restrictive. Reference should be made to the appended claims and their equivalents in determining the scope of the instant disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A computing system comprising:
a memory device that stares parameters of a layer of a neural network that have been compressed; and
a special-purpose hardware processing unit programmed to, for the layer of the neural network:
receive the compressed parameters from the memory device;
decompress the compressed parameters; and
apply the decompressed parameters in an arithmetic operation of the layer of the neural network.

2. The computing system of claim 1, wherein:
the memory device comprises a static memory cache that is local relative to the hardware processing unit; and
the memory devices retains the compressed parameters in the static memory cache while the layer of the neural network is being processed.

3. The computing system of claim 1, wherein the memory device comprises a dynamic memory device that is remote relative to the special-purpose hardware processing unit.

4. The computing system of claim 1, further comprising a compression subsystem that is communicatively coupled to the memory device and configured to compress parameters and store the compressed parameters in the memory device.

5. The computing system of claim 4, wherein the special-purpose hardware processing unit comprises the compression subsystem.

6. The computing system of claim 4, wherein the compression subsystem is configured to compress the parameters by:
distinguishing between sparse and non-sparse data in the parameters; and
apply a compression algorithm to the parameters based on the distinguishing between the sparse and the non-sparse data in the parameters.

7. The computing system of claim 4, wherein the compression subsystem is configured to compress the parameters by implementing a lossy compression algorithm.

8. The computing system of claim 1, wherein the special-purpose hardware processing unit is further programmed to:
update the parameters of the layer;
compress the updated parameters; and
store the compressed, updated parameters in the memory device.

9. The computing system of claim 8, wherein the special-purpose hardware processing unit updates the parameters based on a compression scheme that will be used to update the compress parameters.

10. A special-purpose hardware accelerator comprising:
a processing unit configured to, for a layer of a neural network:
receive parameters for the layer of the neural network from a memory device;
decompress the parameters; and
apply the decompressed parameters in an arithmetic operation; and
a cache that stores the parameters locally on the special-purpose hardware accelerator.

11. The special-purpose hardware accelerator of claim 10, wherein the cache stores the parameters by retaining the parameters in the cache while the layer of the neural network is being processed.

12. The special-purpose hardware accelerator of claim 10, wherein the processing unit is configured to receive the parameters from a memory device that is remote relative to the special-purpose hardware accelerator.

13. The special-purpose hardware accelerator of claim 10, further comprising a compression subsystem that is configured to compress the parameters before the parameters are stored in the cache.

14. The special-purpose hardware accelerator of claim 10, wherein compression of the parameters for storage in the cache is less complex than compression of the parameters for storage in a remote memory device.

15. The special-purpose hardware accelerator of claim 10, wherein the parameters are compressed via a lossy compression scheme.

16. A method comprising:
compressing parameters of a layer of a neural network;
storing the compressed parameters in a memory device;
receiving, at a special-purpose hardware accelerator, the compressed parameters from the memory device;
decompressing, at the special-purpose hardware accelerator, the compressed parameters; and
applying, at the special-purpose hardware accelerator, the decompressed parameters in an arithmetic operation.

17. The method of claim 16, wherein:
the memory device comprises a static memory cache that is local relative to the special-purpose hardware accelerator; and
the static memory cache retains the compressed parameters in the static memory cache while the layer of the neural network is being processed.

18. The method of claim 16, wherein the memory device comprises a dynamic memory device that is remote relative to the special-purpose hardware accelerator.

19. The method of claim 16, wherein compressing the parameters comprises compressing the parameters via a lossy compression algorithm.

20. The method claim 16, further comprising
updating the parameters of the layer;
compressing the updated parameters; and
storing the compressed updated parameters in the memory device.
